(19) United States
(12) Patent Application Publication
(10) Pub. No.: US 2026/0013127 A1
(43) Pub. Date: Jan. 8, 2026

(54) MANAGING PAD-OUT STRUCTURES IN SEMICONDUCTOR DEVICES

(71) Applicant: Yangtze Memory Technologies Co., Ltd., Wuhan (CN)

(72) Inventors: Bin CHEN, Wuhan (CN); Wei XU, Wuhan (CN); Zhipeng WU, Wuhan (CN); Houxiao WU, Wuhan (CN); Jing LIU, Wuhan (CN); Hang YIN, Wuhan (CN); Zongliang HUO, Wuhan (CN)

(21) Appl. No.: 18/797,165

(22) Filed: Aug. 7, 2024

(30) Foreign Application Priority Data
Jul. 3, 2024 (CN) 202410888630.0

(51) Int. Cl. H10B 43/27; H10B 41/27

(52) U.S. Cl. CPC H10B 43/27; H10B 41/27

(57) ABSTRACT

Systems, devices, and methods for managing pad out structures in a semiconductor device are provided. In one aspect, a semiconductor device includes a first stack of conductive layers and isolating layers alternating with each other along a first direction; and a contact structure extending along the first direction and being coupled to a conductive layer of the first stack. The conductive layer extends along a second direction perpendicular to the first direction. The contact structure includes an outer conductive layer and a body surrounded by the outer conductive layer. The semiconductor device also includes a connection structure in contact with the contact structure along the first direction. A first segment of the connection structure at least partially overlaps a first portion of the outer conductive layer of the contact structure along the first direction.

### CROSS-REFERENCE TO RELATED APPLICATIONS

This application claims priority to Chinese Patent Application No. 202410888630.0, filed on Jul. 3, 2024, which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing pad-out structures (e.g., contact structures and connection structures) for gate layers of memory cells in three-dimensional (3D) semiconductor devices.

One aspect of the present disclosure features a semiconductor device, including a first stack of conductive layers and isolating layers alternating with each other along a first direction; and a contact structure extending along the first direction and being coupled to a conductive layer of the first stack, the conductive layer extending along a second direction perpendicular to the first direction. The contact structure includes an outer conductive layer and a body surrounded by the outer conductive layer. The semiconductor device also includes a connection structure in contact with the contact structure along the first direction. A first segment of the connection structure at least partially overlaps a first portion of the outer conductive layer of the contact structure along the first direction.

In some implementations, the semiconductor device further includes a second stack of dielectric layers and isolating layers alternating with each other along the first direction. The second stack is connected to the first stack along the second direction. The contact structure extends through at least part of the second stack along the first direction to a corresponding one of the dielectric layers. The contact structure includes an interconnect structure connected to the conductive layer of the first stack.

In some implementations, a cross section of the outer conductive layer on a plane perpendicular to the first direction has a ring shape.

In some implementations, the connection structure is surrounded by a separation layer. A portion of the body of the contact structure is in contact with the separation layer.

In some implementations, the connection structure includes a plurality of segments includes the first segment. A second segment of the plurality of segments of the connection structure at least partially overlaps a second portion of the outer conductive layer of the contact structure along the first direction.

In some implementations, the first portion of the outer conductive layer is diametrically opposite to the second portion of the outer conductive layer in the plane.

In some implementations, the plurality of segments of the connection structure is adjoined to one another.

In some implementations, the plurality of segments of the connection structure is separated from one another.

In some implementations, adjacent segments of the plurality of segments are on a same side of the contact structure.

In some implementations, one of the plurality of segments of the connection structure has a length along the second direction. The length is equal to or greater than a width of the outer conductive layer along the second direction. The width of the contact structure is a difference between an inner radius of the contact structure and an outer radius of the outer conductive layer in the plane.

In some implementations, a length of the connection structure along the second direction is equal to or greater than an inner diameter of the outer conductive layer along the second direction.

In some implementations, the first segment of the connection structure includes a first portion on the outer conductive layer of the contact structure and a second portion on the body of the contact structure. A first thickness of the first portion of the first segment of the connection structure along the first direction is smaller than a second thickness of the second portion of the first segment of the connection structure along the first direction.

In some implementations, the first segment of the connection structure includes a third portion beyond an outer sidewall of the outer conductive layer along the second direction. A third thickness of the third portion of the first segment of the connection structure along the first direction is greater than the first thickness of the first portion of the first segment of the connection structure.

In some implementations, at least one of the outer conductive layer or the connection structure includes a tungsten (W) layer and a titanium nitride (TiN) layer.

In some implementations, the connection structure is connected to a conductive line along the first direction.

Another aspect of the present disclosure features a method including: forming a first stack of conductive layers and isolating layers alternating with each other along a first direction; forming a contact structure extending along the first direction and being coupled to a conductive layer of the first stack that extends along a second direction perpendicular to the first direction, where the contact structure includes an outer conductive layer and a body surrounded by the outer conductive layer; and forming a connection structure in contact with the contact structure along the first direction, where a first segment of the connection structure at least partially overlaps a first portion of the outer conductive layer of the contact structure along the first direction.

In some implementations, forming the contact structure includes: forming a first hole extending through a second stack along the first direction; depositing a first conductive material to form the outer conductive layer on a sidewall of the first hole; and depositing a dielectric material to form the body in the first hole.

In some implementations, forming the connection structure includes: depositing a separation layer on the contact structure along the first direction; forming a second hole extending through the separation layer along the first direction to expose at least the first portion of the contact structure; and depositing a second conductive material inside the second hole, where the second conductive material is in contact with the first conductive material of the first portion of the contact structure.

In some implementations, a cross section of the outer conductive layer on a plane perpendicular to the first direction has a ring shape.

In some implementations, the connection structure extends partially into the body of the contact structure.

In some implementations, the first conductive material is the same as the second conductive material.

In some implementations, the connection structure is in contact with at least one of an outer sidewall surface or an inner sidewall surface of the outer conductive layer.

Another aspect of the present disclosure features a semiconductor device including: a first stack of conductive layers and isolating layers alternating with each other along a first direction; a contact structure extending along the first direction and being coupled to a conductive layer of the first stack that extends along a second direction perpendicular to the first direction, where the contact structure includes an outer conductive layer and a body surrounded by the outer conductive layer; and a connection structure in contact with the contact structure along the first direction, where a first segment of the connection structure at least partially overlaps a first portion of the outer conductive layer of the contact structure along the first direction, and where the connection structure is in contact with at least one of an outer sidewall surface or an inner sidewall surface of the outer conductive layer. A cross section of the outer conductive layer on a plane perpendicular to the first direction has a ring shape.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a top view of an example semiconductor device.

FIG. 1B illustrates a cross-sectional view of an example semiconductor device in a connection region.

FIGS. 2A-2H illustrate top views of various implementations of a connection structure and a conduct structure.

FIGS. 3A-3F illustrate cross-sections views of various implementations of a connection structure and a conduct structure.

FIGS. 4A-4I illustrate cross-section views of the example semiconductor device of FIG. 1B at various stages of a semiconductor manufacturing process.

FIG. 5 illustrates a flow chart of an example process for forming the example semiconductor device of FIG. 1B.

FIG. 6 illustrates a block diagram of a system.

Like reference numbers and designations in the various drawings indicate like elements. It is also to be understood that the various exemplary implementations shown in the figures are merely illustrative representations and are not necessarily drawn to scale.

### DETAILED DESCRIPTION

Memory devices, like NAND flash memory devices, can be configured to pad out gate layers using pad-out structures. The pad-out structures can couple the NAND memory arrays to BEOL (Back-End-of-Line) metal layers. The pad-out structures can include contact structures and connection structures (also called vias in some cases). The contact structures can connect the gates layers to the connection structures, which in turn couple the gate layers to the BEOL metal layers. In some cases, the connection structures can have a smaller cross-sectional area compared to the contact structures, posing challenges for alignment between them. To enhance the alignment margin, a large conductive plug can be formed in a contact structure to increase a landing area for one or more corresponding connection structures. However, forming such large conductive plug may introduce additional metal defects, potentially lowering the yield of the memory devices.

Implementations of the present disclosure provide semiconductor devices and methods to form such semiconductor devices. In some implementations, a semiconductor device includes a first stack of conductive layers and isolating layers alternating with each other along a first direction; and a contact structure extending along the first direction and being coupled to a conductive layer of the first stack, the conductive layer extending along a second direction perpendicular to the first direction. The contact structure includes an outer conductive layer and a body surrounded by the outer conductive layer. The semiconductor device also includes a connection structure in contact with the contact structure along the first direction. A first segment of the connection structure at least partially overlaps a first portion of the outer conductive layer of the contact structure along the first direction.

Implementations of the present disclosure can provide one or more of the following technical advantages and/or benefits. For example, the techniques enable widening an alignment window between the contact structures and the connection structures without the need for a large conductive plug, thereby reducing the defects associated with the large conductive plug and improving the yield of the memory devices. In some implementations, the connection structures have one or more segments. Different segments can be either separated or adjoined together. In some implementations, the connection structures are elongated in shape and make contact with opposite sides of the outer conductive layer of the contact structure. This double-sided contact enhances redundancy for alignment points, making it more robust against alignment errors. In some implementations, the connection structure wraps around three sides of a portion of the outer conductive layer, increasing contacting surface between the connection structures and the outer conductive layer, potentially reducing the contact resistance.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

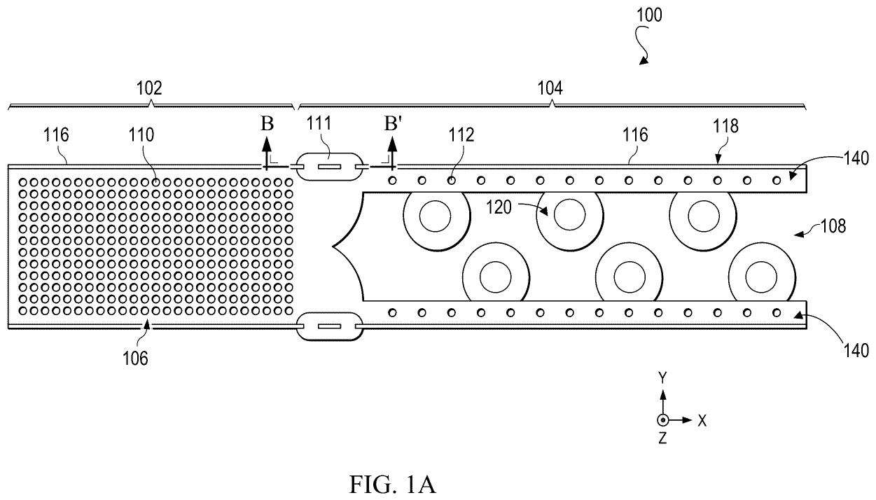

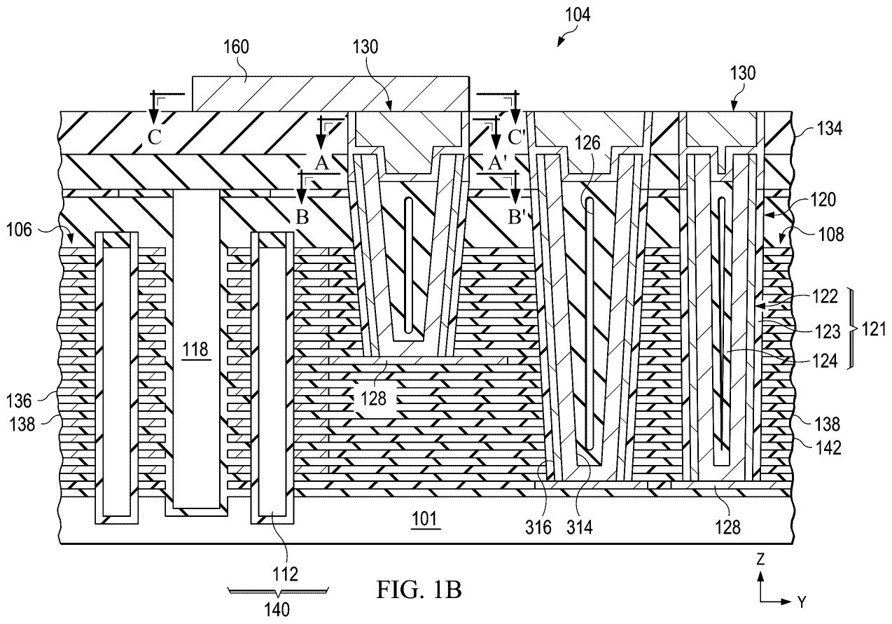

FIG. 1A illustrates a top view of an example semiconductor device 100. In some implementations, the semiconductor device 100 can be a memory device, such as a three-dimensional (3D) NAND memory device. The semiconductor device 100 can include one or more array regions 102 and one or more connection regions 104 configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a first stack 106 of alternating conductive layers and isolating layers (e.g., conductive layers 136 and isolating layers 138 as shown in FIG. 1B). The conductive layers 136 can also be referred to as gate layers 136 in the present disclosure. In some implementations, a part of the first stack 106 can be in the array region 102, and another part of the first stack 106 can be in the connection region 104. The semiconductor device 100 further includes a second stack 108 of alternating dielectric layers and isolating layers (e.g., dielectric layers 142 and isolating layers 138 as shown in FIG. 1B). In some implementations, the second stack 108 can be in the connection region 104. The first stack 106 is connected to the second stack 108. The part of the first stack 106 that is in the connection region 104 can also be referred to as the side connection stack 140 in this disclosure.

The semiconductor device 100 can include an array of channel structures 110 extending through the first stack 106. In some implementations, the array of channel structures 110 is in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the first stack 106. In some implementations, the dummy channel structures 112 are in the connection region 104. For example, some dummy channel structures 112 can be in an edge or peripheral area of the connection region 104. In some instances, the edge area of the connection region 104 is adjacent to the array region 102. In some other instances, the edge area of the connection region 104 is adjacent to a slit structure 118, e.g., in the side connection stack 140. In some implementations, the dummy channel structures 112 are in the array region 102 (e.g., an area adjacent to the connection region 104).

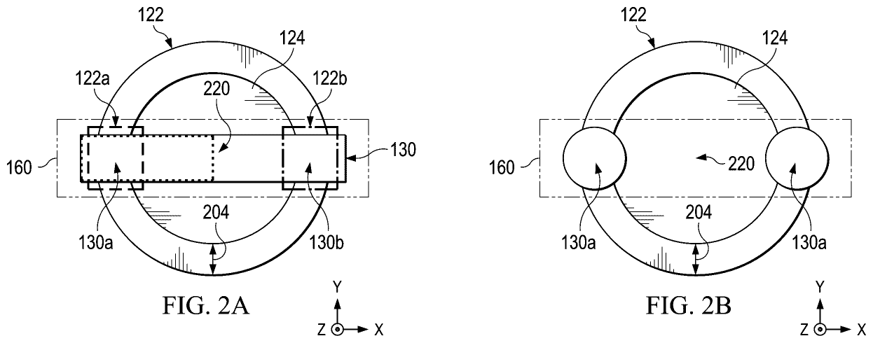

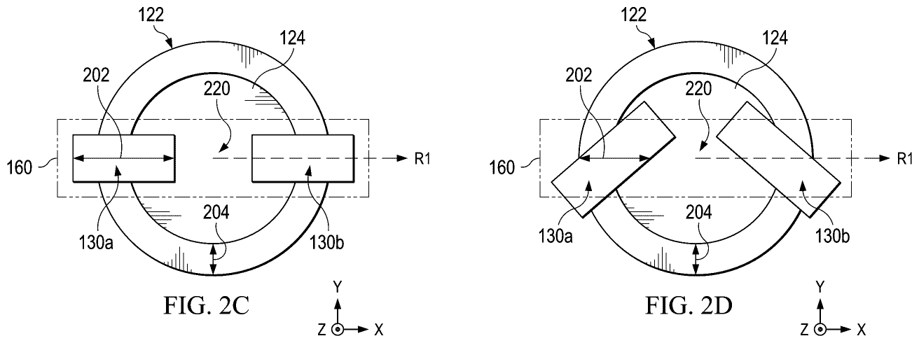

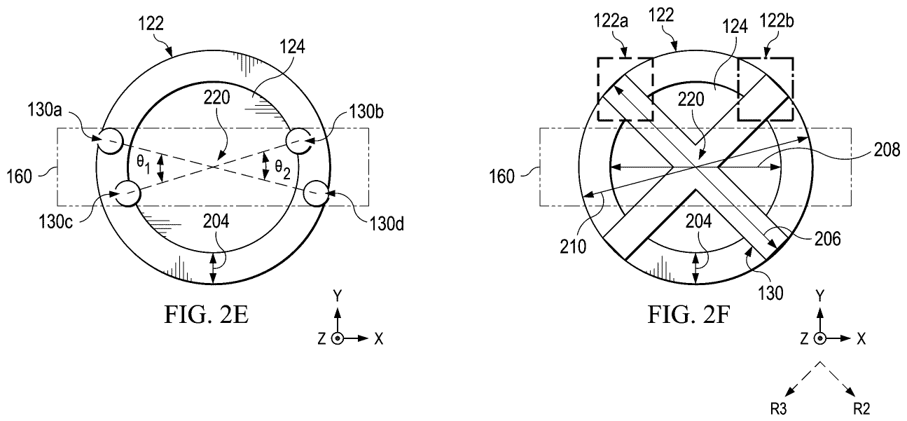

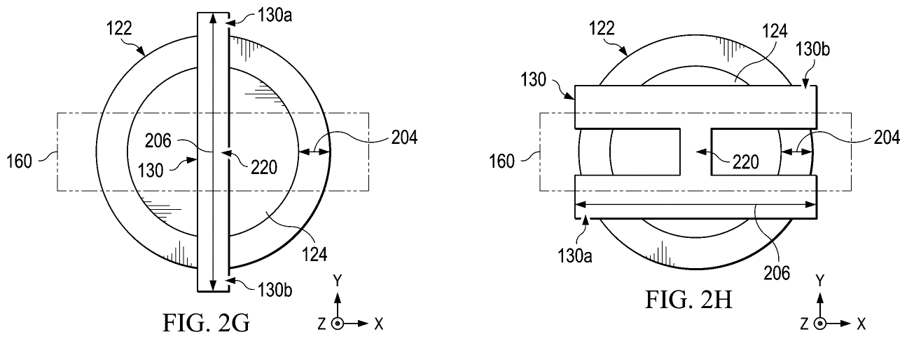

The semiconductor device 100 can include pad-out structures for gate layers 136. The pad-out structures can include contact structures 120 (as illustrated in FIGS. 1A and 1B-3F) and connection structures 130 (as illustrated in FIGS. 1B-3F). The connection structures 130 can also be called vias in some cases. In some implementations, the contact structures 120 are in the connection region 104. The contact structures 120 can connect one or more corresponding gate layers 136 of the first stack 106 to the connection structures 130. These connection structures 130 further couple the gate layers 136 to control circuitries through BEOL metal layers. Alignment between the connection structures 130 and contact structures 120 is crucial because affects electrical connectivity and signal transmission between memory cells and control circuities. In some implementations, the contact structure 120 includes an outer conductive layer 122 with a ring-shaped cross section, e.g., as illustrated in FIGS. 2A-2H.

The semiconductor device 100 can include one or more slit structures 118. Each slit structure 118 can extend in the X direction. The slit structure 118 can extend into both the array region 102 and the connection region 104. In some implementations, the slit structures 118 can divide an array region into multiple memory blocks. In some implementations, the slit structure 118 can function as a common source contact for the channel structures 110 in the array region 102. In some implementations, as shown in FIG. 1A, each slit structure 118 can include multiple segments 116. In some implementations, the adjacent segments 116 are separated and spaced by isolation structures 111 along the X direction. The isolation structures 111 can eliminate or reduce stress built in the slit structure 118 during the manufacturing process, thereby preventing the slit structure 118 from bending or cracking. In some implementations, as shown in FIG. 1A, the isolation structure 111 is in the connection region 104 and is adjacent to the array region 102. In some other implementations, the isolation structure 111 is in the array region 102 and is adjacent to the connection region 104. In some other implementations, the isolation structure 111 can have a portion in the array region 102 and another portion in the connection region 104. In some implementations (not shown in FIG. 1A), the slit structure 118 can further include one or more segments extending along a second horizontal direction (e.g., the Y direction). In some implementations, the slit structure 118 can include multiple segments connected in an H shape or a T shape. In some implementations, the segments 116 of each slit structure 118 can have similar or a same width (e.g., along the Y direction). In some other implementations, the segments 116 of each slit structure 118 can have different widths (e.g., along the Y direction). In some implementations, along the Y direction, a width of the segment 116 in the connection region 104 is larger than a width of the segment 116 in the array region 102. For example, the width of the segment 116 in the connection region 104 can be approximately 1.5 to 2 times that of the segment 116 in the array region 102.

In some implementations, slit structure 118 is an insulating structure that does not include any contact therein (i.e., not functioning as the source contact) and thus, does not introduce parasitic capacitance and leakage current with first conductive layers 136 (gate layers). In some implementations, slit structure 118 is a front-side source contact further including an inner conductive portion (e.g., including W, polysilicon, and/or TiN) circumscribed by a slit spacer.

FIG. 1B illustrates a cross-sectional view of an example connection region 104 of the semiconductor device 100 in Y-Z plane. The semiconductor device 100 can include a substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 101 can be removed from the semiconductor device 100 in a later process of manufacturing the semiconductor device 100. As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 101) in the y-direction (i.e., the vertical direction) when the substrate is positioned in the lowest plane of the 3D memory device in the y-direction.

The semiconductor device 100 can include the first stack 106 and the second stack 108 on the substrate 101. As illustrated in FIG. 1B, the slit structure 118 can extend through the first stack 106 along the vertical direction (e.g., the Z direction) into the substrate 101 along the Z direction. As noted above, the part of the first stack 106 that is between the slit structure 118 and the second stack 108 can be referred to as the side connection stack 140. The dummy channel structures 112 can extend through the side connection stack 140 along the vertical direction (e.g., the Z direction) into the substrate 101. The side connection stack 140 and the second stack 108 can be arranged along Y direction, as illustrated in FIGS. 1A and 1B. In some implementations, the second stack 108 is positioned between two side connection stacks 140 along the Y direction, as illustrated in FIG. 1A.

The second stack 108 have the dielectric layers 142 and the isolating layers 138 that are alternating with each other in the vertical direction (e.g., Z direction) perpendicular to the substrate surface. The isolating layers 138 can also be the same or different from each other in thickness, for example, ranging from 10-500 nm, e.g., about 25 nm. The dielectric layers 142 can be the same or different from each other in thickness, for example, ranging from 10-500 nm, e.g., about 35 nm. It should be noted that the number of the dielectric layers 142 and the isolating layers 138 shown in FIG. 1B is for illustration only and that any suitable number of the dielectric layers 142 and the isolating layers 138 can be included in the second stack 108. The dielectric layer 142 and/or the isolating layers 138 can include a dielectric material, such as silicon oxide, silicon nitride, silicon oxynitride, or any combination thereof. In some implementations, the dielectric layer 142 include silicon nitride, while the isolating layers 138 include silicon oxide.

As noted above, a gate layer 136 for NAND memory cells in the array region 102 can be coupled to a control circuit through a corresponding contact structure 120. Contact structures 120 can extend vertically through the second stack 108 at different depths along the Z direction and land at corresponding dielectric layers 142. A contact structure 120 can include a vertical contact 121 and an interconnect structure 128. The vertical contact 121 can extend vertically through one or more dielectric layers 142 and be in contact with the interconnect structure 128 at its bottom. In some implementations, as shown in FIG. 1B, the vertical contact 121 includes an outer conductive layer 122 and a body 124 surrounded by the outer conductive layer 122. In some implementations, a cross-section of the outer conductive layer 122 on a plane (e.g., X-Y plane) perpendicular to the Z direction has a ring shape, as illustrated in FIGS. 2A-2H. In some implementations, the vertical contact further includes a spacer layer 123. The outer conductive layer 222 can be surrounded by the spacer layer 216. The spacer layer 216 can isolate the outer conductive layer 222 of the contact structure 120 from surrounding material of the second stack 108.

The interconnect structure 128 of the contact structure 120 can be formed by replacing a portion of the corresponding dielectric layer 142 with a conductive material. In some implementations, an area of the interconnect structure 128 is larger than an area of the vertical contact 121 in a cross-sectional plane parallel to the substrate surface (e.g., X-Y plane). In some implementations, the interconnect structure 128 is in contact with a corresponding conductive layer 136 in the side connection stack 140 located in the connection region 104, as illustrated in FIGS. 1A and 1B. As the side connection stack 140 is part of the first stack 106, the contact structure 120 is thus electrically connected to the corresponding gate layer 136 of the first stack 106 in the array region 102, achieving word line pick-up/fan-out.

The outer conductive layers 122 and interconnect structures 128 can have the same conductive material. In some implementations, the conductive material includes, without limitation to, W, Co, Cu, Al, TiN, TaN, polysilicon, or any combination thereof. In some implementations, the outer conductive layers 122 and interconnect structures 128 include multiple conductive layers, such as a W layer over a TiN layer. The spacer layer 123 and/or the body 124 can include, without limitation to, silicon oxide, silicon nitride, silicon oxynitride, or any combination thereof.

The upper end of each contact structure 120 can be in contact with one or more connection structures 130 (also called vias). The connection structures 130 can connect the contact structures to a corresponding conductive line 160 (also called metal layers) for back-end-of-line (BEOL) metal routings. Adjacent connection structures 130 can be isolated by a separation layer 134. In some implementations, the connection structures 130 include any suitable conductive material, such as W, Co, Cu, Al, TiN, polysilicon, doped silicon, silicides, or any combination thereof. In some implementations, the connection structures 130 include a tungsten (W) layer and a titanium nitride (TiN) layer. In some implementations, the separation layer 134 includes dielectric materials including, but not limited to, silicon oxide, silicon nitride, silicon oxynitride, or any combination thereof.

FIGS. 2A-2H illustrate top views of various implementations of a connection structure 130 and a conduct structure 120. It is to be understood that FIGS. 2A-2H can be a composite view with overlays of various cross-section planes that are parallel to the X-Y plane. For example, FIGS. 2A-2H can be a composite view of cross-section planes similar to those through A-A′, B-B′ and C-C′ axis of FIG. 1B, such that FIGS. 2A-2H can illustrate a connection structure 130, a contact structure 120 and a conductive line 160 in a single view. FIGS. 2A-2H are for illustrative purpose only and may not depict a single cross-sectional view within an actual device.

In some implementations, a cross section of the outer conductive layer 122 in a plane (e.g., X-Y plane) perpendicular to the Z direction has a ring shape, as illustrated in FIGS. 2A-2H. The ring shape can be a shape bounded by two concentric loops, e.g., two concentric circles, two concentric squares, or two concentric rectangles. In some implementations, the width 204 of the outer conductive layer 122 is between 50 nm to 1000 nm. The width 204 of the outer conductive layer 122 can be defined as a difference between an inner and outer radius of the outer conductive layer 122 in the plane.

In some implementations, the connection structure 130 includes a plurality of segments, e.g., a first segment 130a and a second segment 130b. The first segment 130a of the connection structure 130 at least partially overlaps a first portion 122a of the outer conductive layer 122 of the contact structure 120 along the first direction, e.g., Z direction. For example, as illustrated in FIG. 2A, the first segment 130a (e.g., enclosed by dot lines) partially covers the first portion 122a (e.g., within the region enclosed by dashed lines) of the outer conductive layer 122. As both the connection structure 130 and the contact structure 120 include conductive materials, this overlapping region creates electrical connections between the connection structure 130 and the contact structure 120.

In some implementations, a second segment 130b of the plurality of segments of the connection structure 130 at least partially overlaps a second portion 122b of the outer conductive layer 122 of the contact structure 120 along the first direction, e.g., Z direction. For example, as illustrated in FIG. 2A, the second segment 130b partially covers the second portion 122b of the outer conductive layer 122 (e.g., within the region enclosed by dash-dot lines).

In some implementations, a first segment 130a and/or the second segment 130b of the connection structure 130 includes at least the region that overlaps with the outer conductive layer 122. Similarly, a first portion 122a and/or a second portion 122b of the outer conductive layer 122 includes at least the region that overlaps with a corresponding segment of the connection structure 130.

In some implementations, the plurality of segments of the connection structure 130 is adjoined to one another, as illustrated in FIGS. 2A, 2F, 2G and 2H. In other words, the connection structure 130 can be a unitary structure. The connection structures 130 can have an elongated shape (e.g., as illustrated in FIGS. 2A and 2G), or a combination of two or more elongated shapes (e.g., as illustrated in FIGS. 2F and 2H).

In some implementations, the plurality of segments of the connection structure 130 is separated from one another, as illustrated in FIGS. 2B, 2C, 2D and 2E. Individual segments of the connection structures 130 can have a circular shape (e.g., as illustrated in FIGS. 2B and 2E), a rectangular shape (e.g., as illustrated in FIGS. 2C and 2D), or any other suitable shapes.

In some implementations, adjacent segments of the plurality of segments are on a same side of the contact structure 120, such that they subtend an angle at the center of the outer conductive layer 122 that is smaller than 180 degrees. For example, as illustrated in FIG. 2E, adjacent segments 130a, 130c of the connection structure 130 are on the same side of the contact structure 120, e.g., the negative X-axis side. They subtend a first acute angle θ1. Likewise, adjacent segments 130b, 130d are on the other side of the contact structure 120, e.g., the positive X-axis side. They subtend a second acute angle θ2.

In some implementations, the first portion 122a of the outer conductive layer 122 is diametrically opposite to the second portion 122b of the outer conductive layer 122 in the X-Y plane, as illustrated in FIGS. 2A-2D and 2G. In some implementations, rather than being diametrically opposite, the first portion 122a of the outer conductive layer 122 is adjacent to the second portion 122b of the outer conductive layer 122 in the X-Y plane, as illustrated in FIG. 2F. In other words, the first and second portions of the outer conductive layer 122 can be on the same side of the outer conductive layer 122.

In some implementations, one segment of the connection structure 130 has a length along the second direction, e.g., a diameter direction that passes through the ring center of the outer conductive layer 122. The length can be equal to or greater than the width of the outer conductive layer 122 along the same direction. For instance, as illustrated in FIGS. 2C and 2D, the length 202 of a segment of the connection structure 130 can be its dimension along the diameter direction R1, and this length 202 can be greater than the width 204 of the contact structure 120.

In some implementations, a length of the connection structure 130 along the second direction is equal to or greater than an inner diameter of the contact structure 120 along the same direction. The second direction can be a diameter direction that passes through the ring center of the outer conductive layer 122. For instance, as illustrated in FIG. 2F, the length 206 of the connection structure 130 along the diameter direction R2 is greater than the inner diameter 208 of the outer conductive layer 122.

In some implementations, a length of the connection structure 130 along the diameter direction is equal to or greater than an outer diameter of the outer conductive layer 122. For instance, as illustrated in FIG. 2F, the length 206 of the connection structure 130 along the diameter direction R2 is approximately equal to the outer diameter 210 of the outer conductive layer 122. In another example, as illustrated in FIG. 2G, the length 206 of the connection structure 130 along the diameter direction is greater the outer diameter of the outer conductive layer 122.

As noted above, the connection instructions 130 can be connected to a conductive line 160. FIGS. 2A-2H illustrate a conductive line 160 extending along X direction. The conductive line 160 can at least partially overlap the connection structure 130. Therefore, the conductive line 160 can electrically be coupled to the contact structure 120 through the connection structure 130. In some implementations, the conductive line 160 connects two or more adjacent connection structures 130.

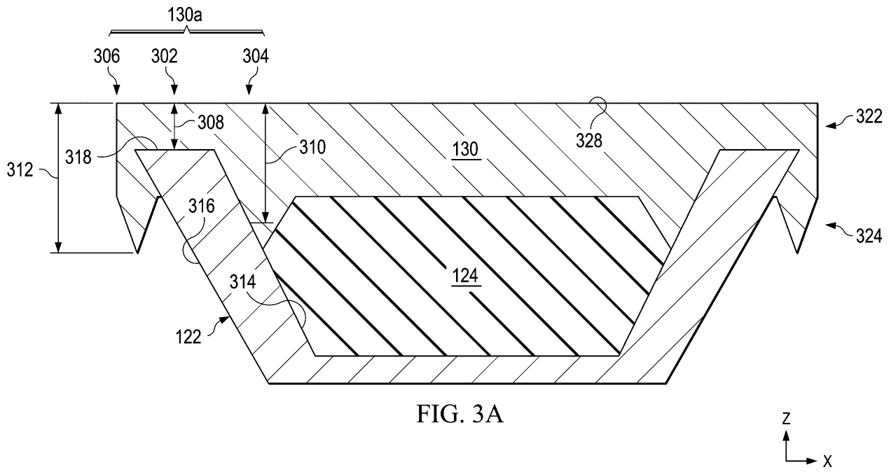

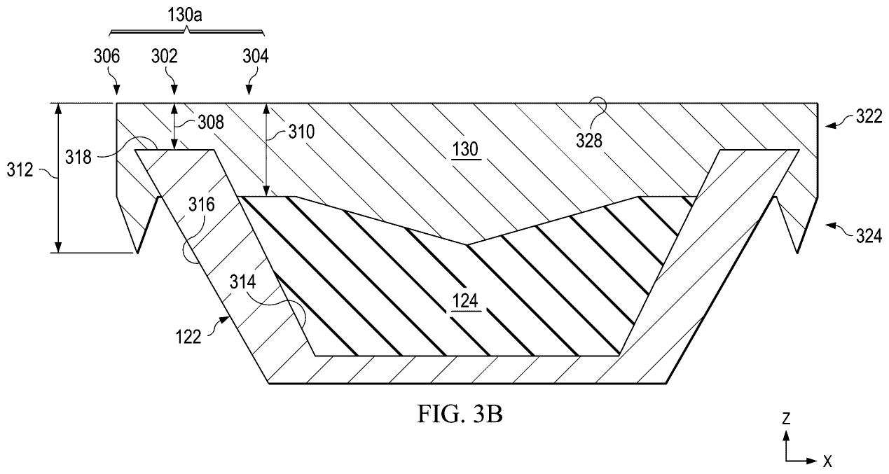

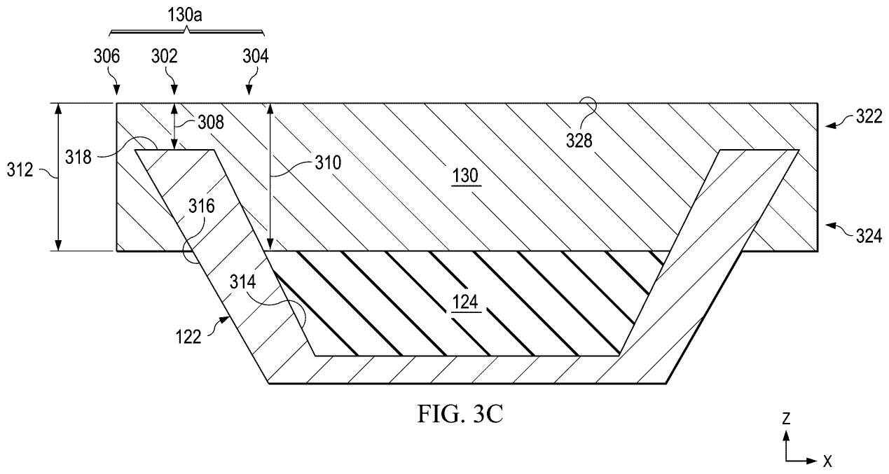

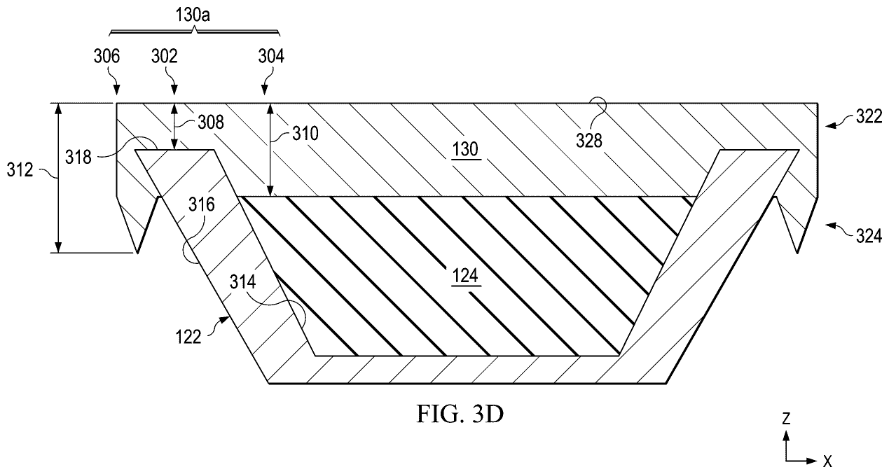

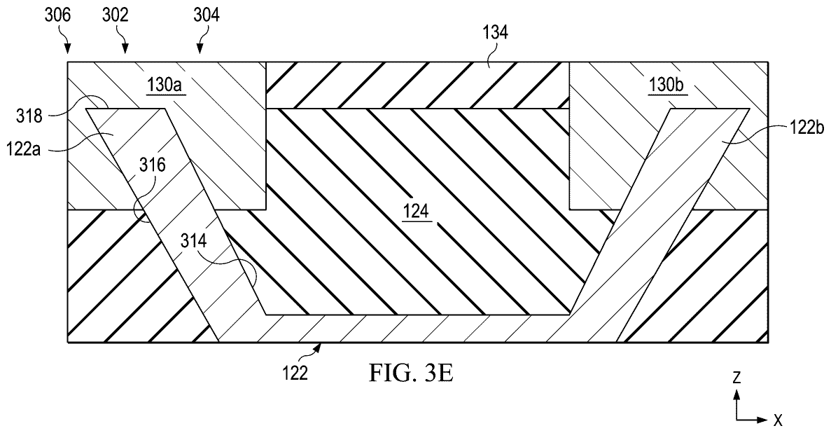

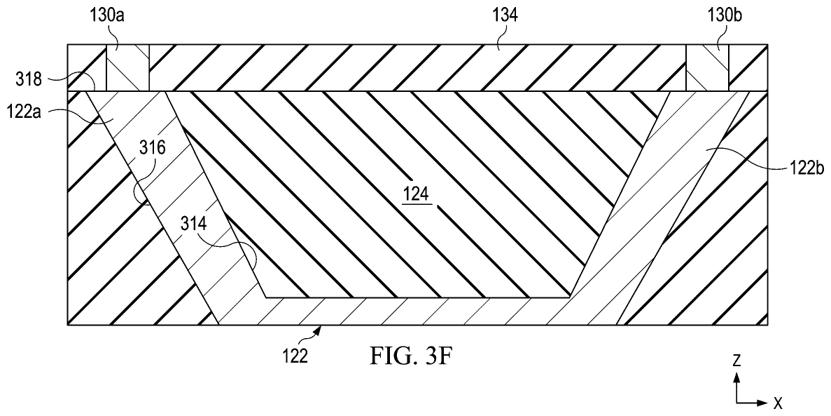

FIGS. 3A-3F illustrate cross-sections views of various implementations of a connection structure 130 and a conduct structure 120. In particular, FIGS. 3A-3D illustrate four example cross-section views of the implementation depicted in FIG. 2A; FIG. 3E illustrates an example cross-section view of the implementation depicted in FIG. 2C; FIG. 3F illustrates an example cross-section view of an implementation similar to the one depicted in FIG. 2E.

In some implementations, as illustrated in FIGS. 3A-3E, the first segment 130a of the connection structure 130 includes a first portion 302 on the outer conductive layer 122 of the contact structure 120 and a second portion 304 on the body 124 of the contact structure 120. A first thickness 308 of the first portion 302 of the first segment 130a of the connection structure 130 along the first direction, e.g., Z direction, is smaller than a second thickness 310 of the second portion 304 of the first segment 130a of the connection structure 130. The first thickness 308 can refer to the distance between the upper surface 328 of the connection structure 130 and the upper surface 318 of the outer conductive layer 122. The second thickness 310 can refer to the average thickness of the second portion 304 (e.g., as illustrated in FIG. 3B), or the maximum distance between the upper surface 328 of the connection structure 130 and the lowest point or surface of the second portion 304 that extends into the body 124 of the contact structure 120 (e.g., as illustrated in FIGS. 3A and 3C). In other words, the connection structure 130 can extend vertically (e.g., along Z direction) into the body 124 of the contact structure 120 such that the connection structure 130 is in contact with an inner sidewall surface 314 of the outer conductive layer 122.

In some implementations, the first segment 130a of the connection structure 130 includes a third portion 306 beyond an outer sidewall 316 of the outer conductive layer 122 along the second direction, e.g., X direction. A third thickness 312 of the third portion 306 of the first segment 130a of the connection structure 130 along the Z direction can be greater than the first thickness 308 of the first portion 302 of the first segment 130a of the connection structure 130. The third thickness 312 can refer to the average thickness of the third portion 306 (e.g., as illustrated in FIG. 3C), or the maximum distance between the upper surface 328 of the connection structure 130 and the lowest point or surface of the third portion 306 that is outside of the outer conductive layer 122 (e.g., as illustrated in FIG. 3A). In other words, the connection structure 130 can laterally extend beyond the outer edge of the outer conductive layer 122 along X direction and vertically extend into the separation layer 134 (e.g., as illustrated in FIG. 1B). The connection structure 130 can be in contact with an outer sidewall surface 316 of the outer conductive layer 122.

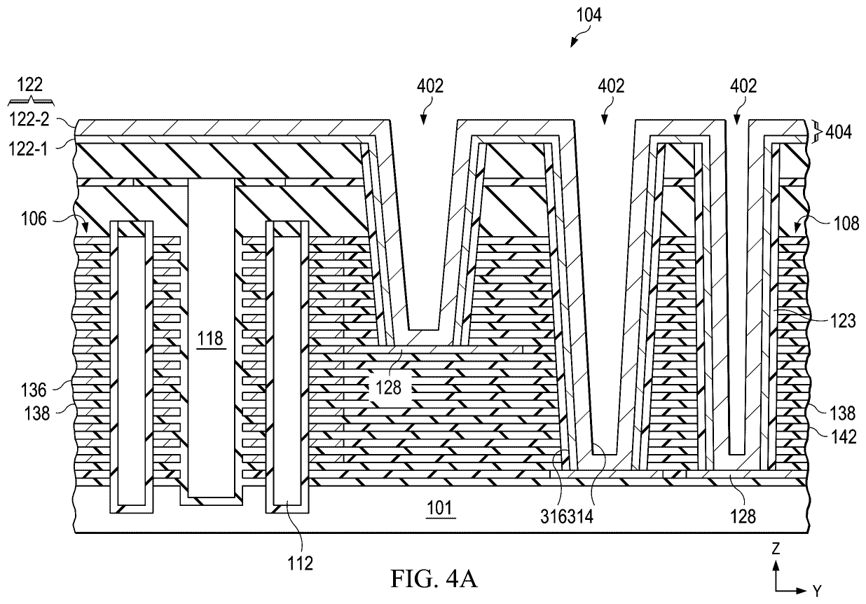

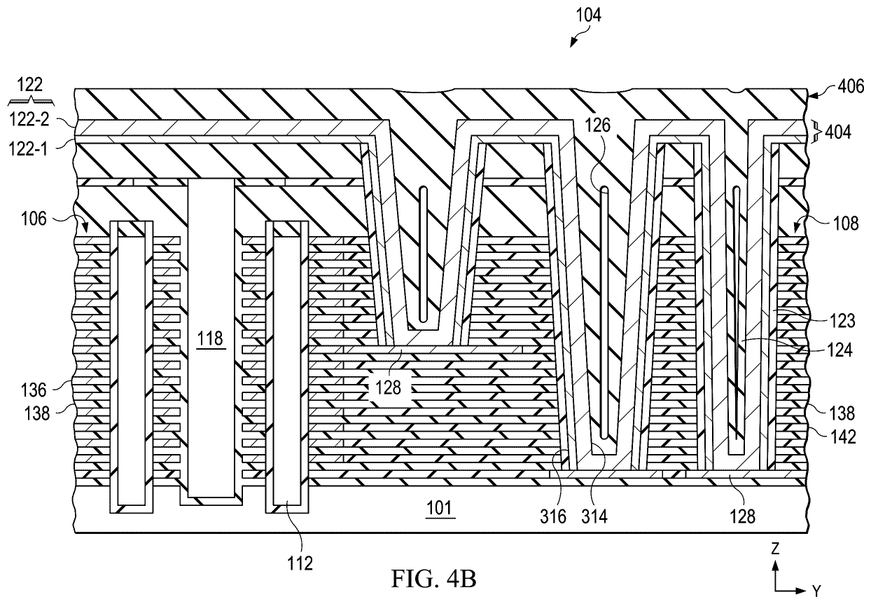

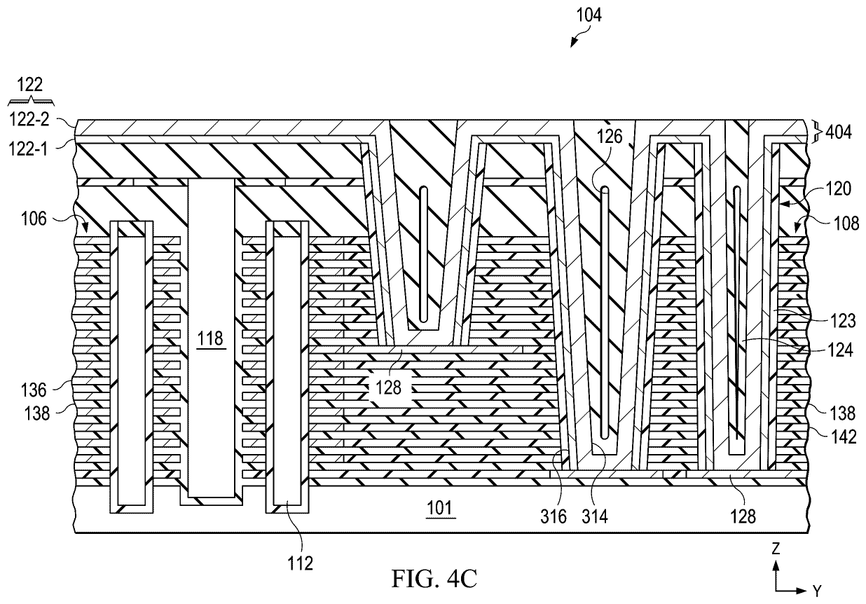

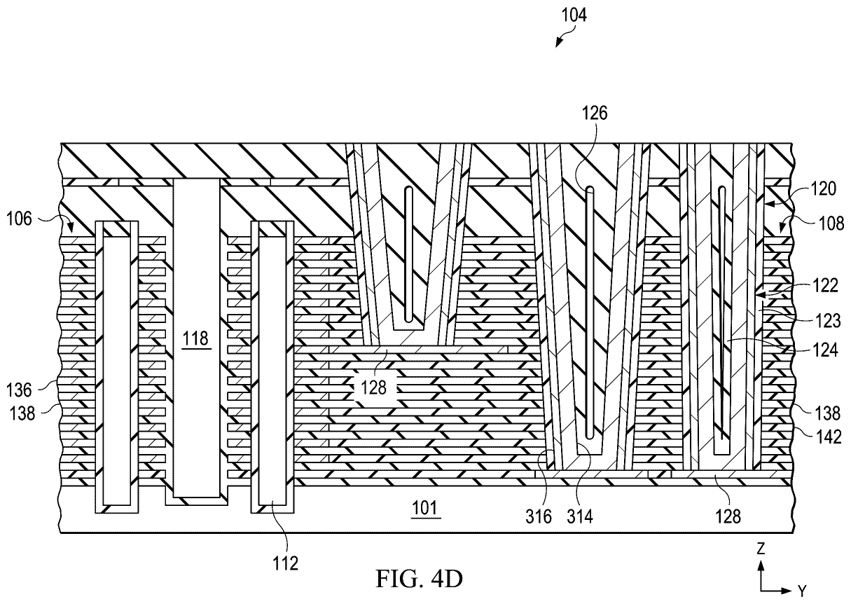

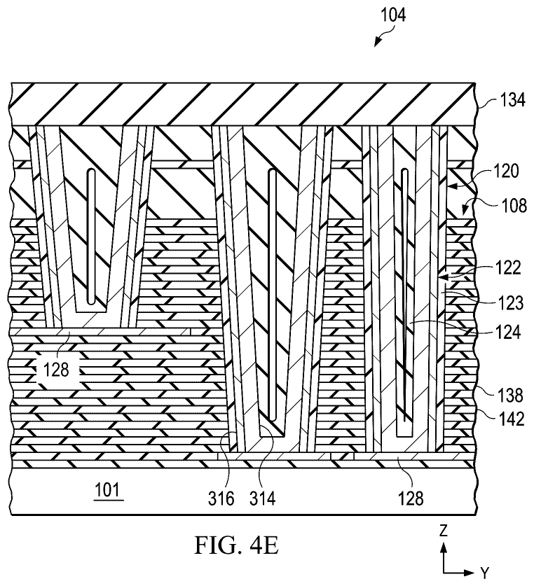

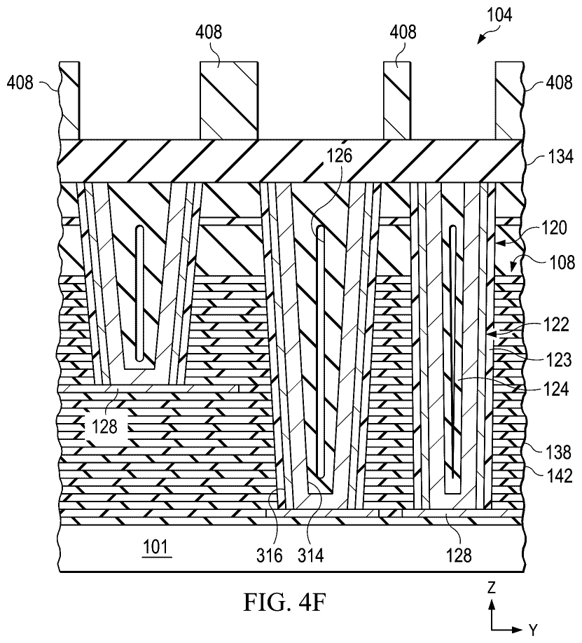

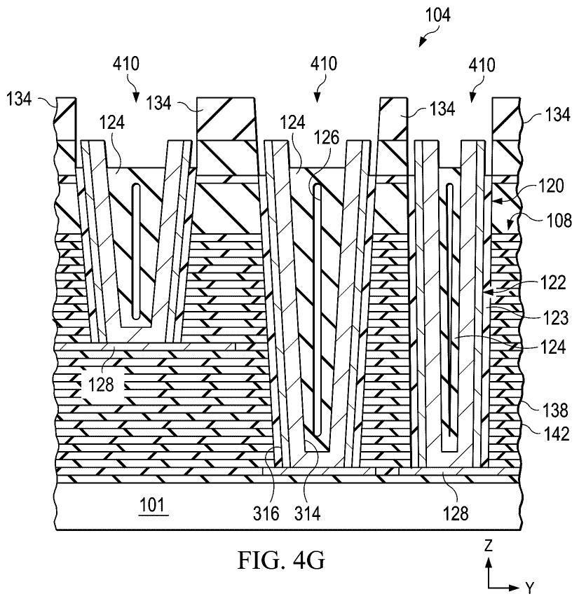

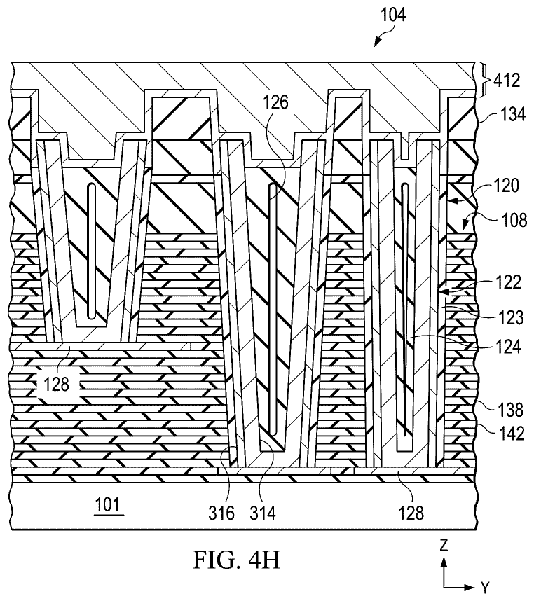

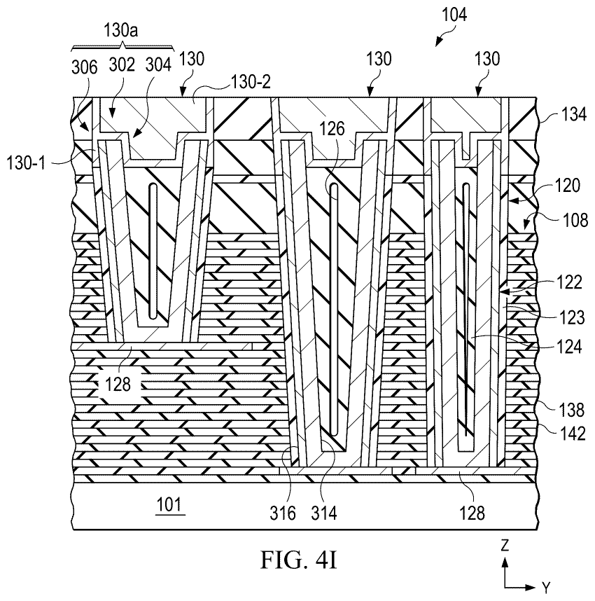

In some implementations, as illustrated in FIGS. 3A-3E, the connection structure 130 wraps around three sides of the outer conductive layer 122 such that the connection structure 130 can be in contact with three surfaces of the outer conductive layer 122, e.g., the outer sidewall surface 316, the inner sidewall surface 314 and the upper surface 318. This non-planar configuration can result from a hole etching process in the separation layer 134 along the Z direction, as described with further details below in reference to FIG. 4G.

As illustrated in FIGS. 3A-3D, the second portion 304 and the third portion 306 can have different shapes or configurations. The second portion 304 and the third portion 306 can each have an upper part 322 and a lower part 324. The lower part 324 of the second portion 304 and/or the third portion 306 can be the part that is closer to the substrate 101 of the semiconductor device. In some implementations, the lower part 324 of the second portion 304 and/or the third portion 306 has a sharp tip or a triangle shape as illustrated in FIGS. 3A, 3B and 3D. In some implementations, the lower part 324 of the second portion 304 and/or the third portion 306 has a flat shape, as illustrated in FIGS. 3C and 3E. In some implementations, the second thickness 310 and the third thickness 312 are identical or substantial similar to each other, as illustrated in FIGS. 3C and 3E. In some implementations, the second thickness 310 is smaller than the third thickness 312, as illustrated in FIGS. 3B and 3D. In some implementations, the connection structure 130 extends deeper into the body 124 of the contact structure 120 in the center of the body 124, as illustrated in FIG. 3B.

As illustrated in FIG. 3E, which shows an example cross-section view of the implementation depicted in FIG. 2C, the first segment 130a and the second segment 130b can be disconnected. The first segment 130a can wrap around three sides of first portion 122a of the outer conductive layer 122, and the second segment 130b can wrap around three sides of second portion 122b of the outer conductive layer 122. In some implementations, a portion of the body 124 of the contact structure 120 is in contact with the separation layer 134 that is used to isolate adjacent connection structures 130. The separation layer 134 can have the same material as the body 124 of the contact structure 120.

As illustrated in FIG. 3F, which shows an example cross-section view of an implementation similar to the one depicted in FIG. 2E, instead of wrapping around the outer conductive layer 122, the first segment 130a can be in contact with only the upper surface 318 of the outer conductive layer 122.

FIGS. 4A-4I illustrate cross-section views of an example semiconductor device at various stages of a semiconductor manufacturing process. The example semiconductor device can be a 3D semiconductor device 100 of FIGS. 1A and 1B, or a part of the 3D semiconductor device 100 of any one of FIGS. 2A-3F. The cross-section views can be in Y-Z plane. FIGS. 4A-4D illustrate the cross-section views of both the first and second stacks in the connection region 104 of the example semiconductor device, while FIGS. 4E-4I illustrates the cross-sectional view of only the second stack for case of illustration.

As illustrated in FIG. 4A, the first stack 106 and the second stack 108 can be formed on the substrate 101. The second stack 108 can be connected to the first stack 106. The isolating layers 138 can extend into both the first stack 106 and the second stack 108 along the second horizontal direction (e.g., Y direction) in the connection region 104. A dielectric layer 142 in the second stack 108 can be in contact with a corresponding conductive layer 136 in the first stack 106. To form the first stack 106 and the second stack 108, a series of alternating dielectric layers 142 (also called sacrificial layers in some cases) and isolating layers 138 can be first deposited. The dielectric layers 142 in the region of the first stack 106 can be subsequently etched away, e.g., through an opening formed in the position of the slit structure 118, while dielectric layers 142 in the second stack 108 remain unchanged. Then, the conductive layers 136 can be formed in replace of the dielectric layers 142 in the region of the first stack 106 to form the first stack 106.

The first holes 402 can be formed extending through the second stack 108 at different depths along the first direction, e.g., Z direction, according to some implementations. The top surfaces of different first holes 402 can be flush with one another, while the bottom surfaces of different first holes 402 can extend to different levels, for example, different dielectric layers 142 of the second stack 108. Forming first holes 402 can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

In some implementations, part of the dielectric layers 142 can be removed through the first holes 402, which is subsequently filled with a conductive material to form the interconnect structures 128. In some implementations, the interconnect structures 128 have a circular shape in the X-Y plane. In some implementations, an area of the interconnect structure 128 is larger than an area of the first holes 402 in the X-Y plane.

A conductive material can be deposited on a sidewall of the first holes 402 to form the outer conductive layer 122. The outer conductive layer 122 connects to the interconnect structures 128. The outer conductive layer 122 can include, but not limited to, W, Co, Cu, Al, TiN, TaN, polysilicon, silicide, or any combination thereof. In some implementations, the outer conductive layer 122 includes multiple conductive layers, such as a W layer over a TiN layer. For example, the outer conductive layer 122 includes a first layer 122-1 and a second layer 122-2. The first layer 122-1 can be a TiN layer, while the second layer 122-2 can be a W layer. The outer conductive layer 122 can be deposited by one or more thin film deposition processes including, but not limited to, CVD, PVD, ALD, Metal-Organic Chemical Vapor Deposition (MOCVD), sputtering, electroplating, electroless plating, electron-beam evaporation, or any combination thereof. During the deposition of the outer conductive layer 122, the conductive material can be also deposited on surfaces other than the first holes 402, forming a top conductive layer 404.

As illustrated in FIG. 4B, a dielectric material can be deposited in the first holes 402 to form the body 124. The dielectric material of the body 124 can include, but not limited to, silicon oxide, silicon nitride, silicon oxynitride, or any combination thereof. The body 124 can be deposited by one or more thin film deposition processes including, but not limited to, CVD, PVD, ALD, MOCVD, MBE, sputtering, or any combination thereof. In some implementations, air gaps 126 are formed in the body 124 of the first holes 402 during the deposition process. It is to be understood that depending on deposition techniques and dimensions of first holes 402, the air gaps 126 may not be present. During the deposition of the body 124, a top dielectric layer 406 can also be formed on the top conductive layer 404.

As illustrated in FIG. 4C, a polishing process is performed to remove the top dielectric layer 406 and expose the underlying top conductive layer 404. The polishing process can include, but not limited to, chemical mechanical polishing (CMP), mechanical polishing, electrochemical polishing, ultrasonic polishing, or any combination thereof.

As illustrated in FIG. 4D, another polishing process is performed to remove the top conductive layer 404. At this stage, the contact structures 120 can be electrically isolated from one another. Compared to the polishing techniques for the top dielectric layer 406, polishing conductive layers can involve different slurry compositions, PH levels, or abrasive types to facilitate the removal of metal.

As illustrated in FIG. 4E, a separation layer 134 is deposited above the contact structure 120 along the first direction, e.g., Z direction. The separation layer 134 can have the same dielectric material as the body 124 of the contact structure 120 and/or the isolating layers 138 of the second stack 108. The separation layer 134 can include, but not limited to, silicon oxide, silicon nitride, silicon oxynitride, or any combination thereof. The separation layer 134 can be deposited utilizing the deposition techniques describe above.

As illustrated in FIG. 4F, a patterned photoresist layer 408 can be formed on top of the separation layer 134. The patterned photoresist layer 408 can be used to transfer the pattern onto the separation layer 134 during subsequent etching process. The patterned photoresist layer 408 can either be positive or negative, depending on whether they become soluble or insoluble when exposed to light. It is to be noted that the example fabrication process in FIGS. 4F-4I is shown as being implemented with the contact structure 120 and the connection structure 130 depicted in FIGS. 2A and 3C. However, this example fabrication process can be applicable with any other implementations depicted in FIGS. 2A-3F.

As illustrated in FIG. 4G, second holes 410 can be formed which extend through the separation layer 134 along the first direction (e.g., Z direction) to expose at least the first portion 122a of the outer conductive layer 122. This etching process can involve selective etching, where the etchants only remove the dielectric layer or have a higher etch rate for the dielectric layer than for the conductive layer. As the body 124 of the contact structure 120 and the second stack 108 structure can also be made of a dielectric material, they can be partially etched during this etching process. In some implementations, the second holes 410 extend further into the body 124 of the contact structure 120 as illustrated in FIG. 4G, such that the inner sidewall surface 314 of the outer conductive layer 122 is partially exposed. In some implementations, the second holes 410 extend beyond the outer circumference of the outer conductive layer 122, such that the outer sidewall surface 316 of the outer conductive layer 122 is partially exposed. The patterned photoresist layer 408 can be subsequently removed.

As illustrated in FIG. 4H, a second conductive material can be deposited inside the second holes 410. The second conductive material can be in contact with the first conductive material of the outer conductive layer 122 of the contact structure 120. In some implementations, the second conductive material is identical or substantially similar to the first conductive material. In some implementations, the second conductive material includes two layers, a first layer 130-1 made of TiN, and a second layer 130-2 made of W. The first layer 130-1 (e.g., TiN) can be first deposited on the sidewalls of the second holes 410. The first layer 130-1 can be in contact with the body 124 of the contact structure 120, the inner sidewall surface 314 of the outer conductive layer 122 and the outer sidewall surface 316 of the outer conductive layer 122. The second layer 130-2 can be subsequently formed on the first layer 130-1 to fill the vacancies inside the second holes 410. During the deposition process of the second layer 130-2, the second conductive layer 412 can be formed on the separation layer 134.

As illustrated in FIG. 4I, which is similar to the second stack 108 in FIG. 1B, a polishing process can be performed to remove the second conductive layer 412 such that adjacent connection structures 130 are electrically isolated from each other at this stage. As described above in reference to FIGS. 3A-3E, the thickness of the second portion 304 of the first segment 130a of connection structure 130 along Z direction can be greater than that of the first portion 302 of the first segment 130a. Likewise, the thickness of the third portion 306 of the first segment 130a of connection structure 130 along Z direction can also be greater than that of the first portion 302. Although only the first layer 130-1 is depicted in the third portion 306, it is understood that the third portion 306 can include both the first layer 130-1 and the second layer 130-2. The polishing process at this step can involve techniques including without limitations to include, but not limited to, chemical mechanical polishing (CMP), mechanical polishing, electrochemical polishing, ultrasonic polishing, or any combination thereof.

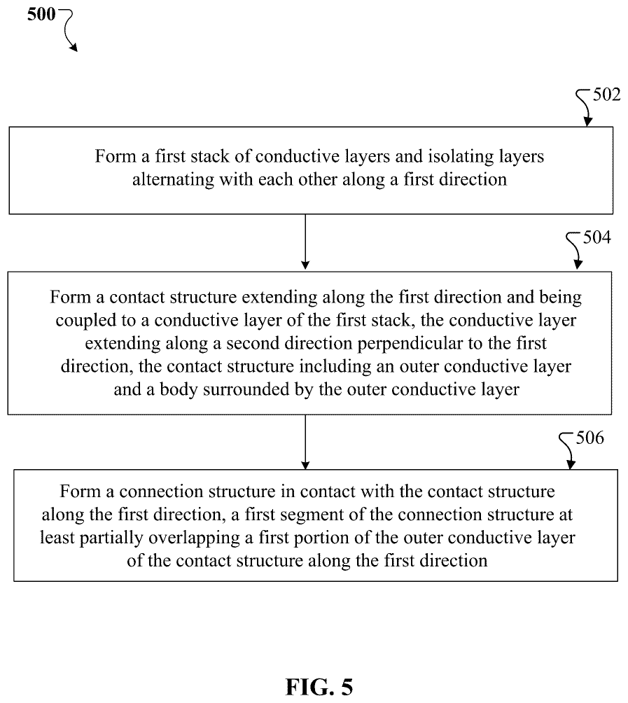

FIG. 5 illustrates a flow chart of an example process 500 for forming the example semiconductor device 100, e.g., the 3D semiconductor device 100 of FIGS. 1A and 1B, or a part of the 3D semiconductor device 100 of any one of FIGS. 2A-3F, or a structure at an intermediate fabrication process of the 3D semiconductor device 100 of FIGS. 4A-4I.

At step 502, a first stack of conductive layers and isolating layers alternating with each other along a first direction is formed. The first stack can be, e.g., the first stack 106 of FIGS. 1A, 1B and 4A-4D. The conductive layers can be, e.g., the conductive layers 136 of FIGS. 1B and 4A-4D. The isolating layers can be, e.g., the isolating layers 142 of FIGS. 1B and 4A-4I. The first direction can be a vertical direction that is perpendicular to a substrate surface, e.g., Z direction.

At step 504, a contact structure is formed, extending along the first direction and being coupled to a conductive layer of the first stack. The conductive layer extends along a second direction perpendicular to the first direction. The contact structure includes an outer conductive layer and a body surrounded by the outer conductive layer. The contact structure can be, e.g., the contact structure 120 of FIGS. 1A-4I. The second direction can be a lateral direction, e.g., the X direction. The outer conductive layer can be, e.g., the outer conductive layer 122 of FIGS. 1B-4I. The body can be, e.g., the body 124 of FIGS. 1B-3F and 4B-4I.

At step 506, a connection structure is formed which is in contact with the contact structure along the first direction. A first segment of the connection structure at least partially overlaps a first portion of the outer conductive layer of the contact structure along the first direction. The connection structure can be, e.g., the connection structure 130 of FIGS. 1B-3F and 4H-4I. The first segment of the connection structure can be, e.g., the first segment 130a of the connection structure 130 of FIGS. 1B-3F and 4H-4I. The first portion of the outer conductive layer can be, e.g., the first portion 122a of the outer conductive layer 122 of FIGS. 1B-3F and 4H-4I.

In some implementations, forming the contact structure includes forming a first hole extending through a second stack along the first direction; depositing a first conductive material to form the outer conductive layer on a sidewall of the first hole; and depositing a dielectric material to form the body in the first hole. The first hole can be, e.g., the first hole 402 of FIG. 4A.

In some implementations, forming the connection structure includes: depositing a separation layer on the contact structure along the first direction; forming a second hole extending through the separation layer along the first direction to expose at least the first portion of the contact structure; and depositing a second conductive material inside the second hole, wherein the second conductive material is in contact with the first conductive material of the first portion of the contact structure. The separation layer can be, e.g., the separation layer 134 of FIGS. 1B and 4E-4I. The second hole can be, e.g., the second hole 410 of FIG. 4G.

In some implementations, a cross section of the outer conductive layer on a plane perpendicular to the first direction has a ring shape, as illustrated in FIGS. 2A-2H.

In some implementations, the connection structure extends partially into the body of the contact structure, as illustrated in FIGS. 1B, 3A-3E, 4H and 4I.

In some implementations, the first conductive material is the same as the second conductive material. The first conductive material and/or the second conduct material can include a TiN layer and a W layer.

In some implementations, the connection structure is in contact with at least one of an outer sidewall surface or an inner sidewall surface of the outer conductive layer. The outer sidewall surface can be, e.g., the outer sidewall surface 316 of FIGS. 1B and 3A-4I. The inter sidewall surface can be, e.g., the inner sidewall surface 314 of FIGS. 1B and 3A-4I.

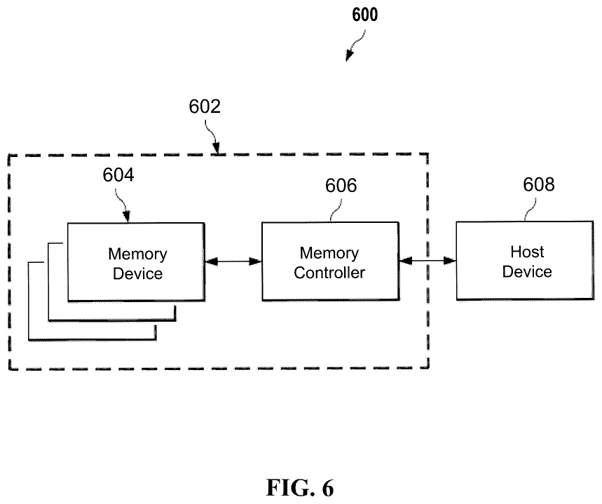

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIGS. 1A and 1B, or a part of the 3D semiconductor device 100 of FIGS. 2A-3F, or a structure at an intermediate fabrication process of the 3D semiconductor device 100 of FIGS. 4A-4I.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for case of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect structures, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction;
a contact structure extending along the first direction and being coupled to a conductive layer of the first stack, the conductive layer extending along a second direction perpendicular to the first direction, wherein the contact structure comprises an outer conductive layer and a body surrounded by the outer conductive layer; and
a connection structure in contact with the contact structure along the first direction, wherein a first segment of the connection structure at least partially overlaps a first portion of the outer conductive layer of the contact structure along the first direction.

2. The semiconductor device of claim 1, further comprising a second stack of dielectric layers and isolating layers alternating with each other along the first direction,
wherein the second stack is connected to the first stack along the second direction, and the contact structure extends through at least part of the second stack along the first direction to a corresponding one of the dielectric layers, and
wherein the contact structure comprises an interconnect structure connected to the conductive layer of the first stack.

3. The semiconductor device of claim 1, wherein a cross section of the outer conductive layer on a plane perpendicular to the first direction has a ring shape.

4. The semiconductor device of claim 1, wherein the connection structure is surrounded by a separation layer, and wherein a portion of the body of the contact structure is in contact with the separation layer.

5. The semiconductor device of claim 3, wherein the connection structure comprises a plurality of segments including the first segment, and wherein a second segment of the plurality of segments of the connection structure at least partially overlaps a second portion of the outer conductive layer of the contact structure along the first direction.

6. The semiconductor device of claim 5, wherein the first portion of the outer conductive layer is diametrically opposite to the second portion of the outer conductive layer in the plane.

7. The semiconductor device of claim 5, wherein the plurality of segments of the connection structure is adjoined to one another.

8. The semiconductor device of claim 5, wherein the plurality of segments of the connection structure is separated from one another.

9. The semiconductor device of claim 8, wherein adjacent segments of the plurality of segments are on a same side of the contact structure.

10. The semiconductor device of claim 5, wherein one of the plurality of segments of the connection structure has a length along the second direction, the length being equal to or greater than a width of the outer conductive layer along the second direction, the width of the contact structure being a difference between an inner radius of the contact structure and an outer radius of the outer conductive layer in the plane.

11. The semiconductor device of claim 1, wherein a length of the connection structure along the second direction is equal to or greater than an inner diameter of the outer conductive layer along the second direction.

12. The semiconductor device of claim 1, wherein the first segment of the connection structure comprises a first portion on the outer conductive layer of the contact structure and a second portion on the body of the contact structure, and wherein a first thickness of the first portion of the first segment of the connection structure along the first direction is smaller than a second thickness of the second portion of the first segment of the connection structure along the first direction.

13. The semiconductor device of claim 12, wherein the first segment of the connection structure comprises a third portion beyond an outer sidewall of the outer conductive layer along the second direction, and wherein a third thickness of the third portion of the first segment of the connection structure along the first direction is greater than the first thickness of the first portion of the first segment of the connection structure.

14. A method, comprising:
forming a first stack of conductive layers and isolating layers alternating with each other along a first direction;
forming a contact structure extending along the first direction and being coupled to a conductive layer of the first stack that extends along a second direction perpendicular to the first direction, wherein the contact structure comprises an outer conductive layer and a body surrounded by the outer conductive layer; and
forming a connection structure in contact with the contact structure along the first direction, wherein a first segment of the connection structure at least partially overlaps a first portion of the outer conductive layer of the contact structure along the first direction.

15. The method of claim 14, wherein forming the contact structure comprises:
forming a first hole extending through a second stack along the first direction;
depositing a first conductive material to form the outer conductive layer on a sidewall of the first hole; and
depositing a dielectric material to form the body in the first hole.

16. The method of claim 15, wherein forming the connection structure comprises:
depositing a separation layer on the contact structure along the first direction;
forming a second hole extending through the separation layer along the first direction to expose at least the first portion of the contact structure; and
depositing a second conductive material inside the second hole, wherein the second conductive material is in contact with the first conductive material of the first portion of the contact structure.

17. The method of claim 14, wherein a cross section of the outer conductive layer on a plane perpendicular to the first direction has a ring shape.

18. The method of claim 14, wherein the connection structure extends partially into the body of the contact structure.

19. The method of claim 14, wherein the connection structure is in contact with at least one of an outer sidewall surface or an inner sidewall surface of the outer conductive layer.

20. A semiconductor device, comprising:
a first stack of conductive layers and isolating layers alternating with each other along a first direction;
a contact structure extending along the first direction and being coupled to a conductive layer of the first stack that extends along a second direction perpendicular to the first direction, wherein the contact structure comprises an outer conductive layer and a body surrounded by the outer conductive layer; and
a connection structure in contact with the contact structure along the first direction, wherein a first segment of the connection structure at least partially overlaps a first portion of the outer conductive layer of the contact structure along the first direction, and wherein the connection structure is in contact with at least one of an outer sidewall surface or an inner sidewall surface of the outer conductive layer,
wherein a cross section of the outer conductive layer on a plane perpendicular to the first direction has a ring shape.
